(19) United States
(12) Patent Application Publication
(10) Pub. No.: US 2024/0429133 A1
(43) Pub. Date: Dec. 26, 2024

(54) SEMICONDUCTOR DEVICE

(71) Applicant: Rohm Co., Ltd., Kyoto-shi (JP)

(72) Inventor: Tsunehisa ONO, Kyoto-shi (JP)

(21) Appl. No.: 18/829,980

(22) Filed: Sep. 10, 2024

Related U.S. Application Data
(63) Continuation of application No. PCT/JP2023/005252, filed on Feb. 15, 2023.

(30) Foreign Application Priority Data
Mar. 17, 2022 (JP) 2022-043176

(51) Int. Cl. H01L 23/495; H01L 23/00; H01L 23/31

(52) U.S. Cl. CPC H01L 23/49541; H01L 24/48; H01L 23/3107; H01L 24/32; H01L 24/73; H01L 2224/32245; H01L 2224/48175; H01L 2224/73265

(57) ABSTRACT

A semiconductor device includes: a semiconductor element including a plurality of electrodes; a first lead including a first pad portion and a first terminal portion; a second lead including a second pad portion and a second terminal portion; a plurality of wires; and a sealing resin. Each of the wires is electrically bonded to one of the plurality of electrodes and to one of the first pad portion and the second pad portion. As viewed in a third direction, a length of a straight line connecting a center of the first pad portion and a center of the second pad portion is defined as a first section length. As viewed in the third direction, a length of a straight line connecting a center of the first terminal portion and a center of the second terminal portion is defined as a second section length. The second section length is different from the first section length.

### TECHNICAL FIELD

The present disclosure relates to a semiconductor device.

### BACKGROUND ART

JP-A-2020-188078 discloses an example of a semiconductor device provided in a small outline package (SOP). The semiconductor device includes a semiconductor chip, a plurality of leads, a plurality of wires electrically bonded to the semiconductor chip and the leads, and a sealing resin covering the semiconductor chip. Each lead includes a portion (outer lead) exposed from the sealing resin. Each wire is electrically bonded to a portion (inner lead) of one of the leads that is covered with the sealing resin.

When the semiconductor device disclosed in JP-A-2020-188078 is mounted onto a wiring board, there may be a case where the wiring pattern of the wiring board is dense. In this case, it is necessary to shorten the distance between the portions of two adjacent leads that are exposed from the sealing resin. As a result, the size of the portion of each of the two adjacent leads that is covered with the sealing resin will be decreased. This causes a decrease in the bonding area of each lead with respect to a wire, thus leading to a decrease in the bonding strength of the wire to the lead.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, with a sealing resin shown transparent.

FIG. 3 is a bottom view showing the semiconductor device in FIG. 1.

FIG. 4 is a right-side view showing the semiconductor device in FIG. 1.

FIG. 5 is a front view showing the semiconductor device in FIG. 1.

FIG. 6 is a cross-sectional view along line VI-VI in FIG. 2.

FIG. 7 is a cross-sectional view along line VII-VII in FIG. 2.

FIG. 8 is a partially enlarged view of FIG. 2.

FIG. 9 is a partially enlarged view of FIG. 8.

FIG. 10 is a plan view showing a semiconductor device according to a second embodiment of the present disclosure, with a sealing resin shown transparent.

FIG. 11 is a front view showing the semiconductor device in FIG. 10.

FIG. 12 is a partially enlarged view of FIG. 10.

### DETAILED DESCRIPTION OF EMBODIMENTS

Embodiments of the present disclosure will be described with reference to the accompanying drawings.

### First Embodiment

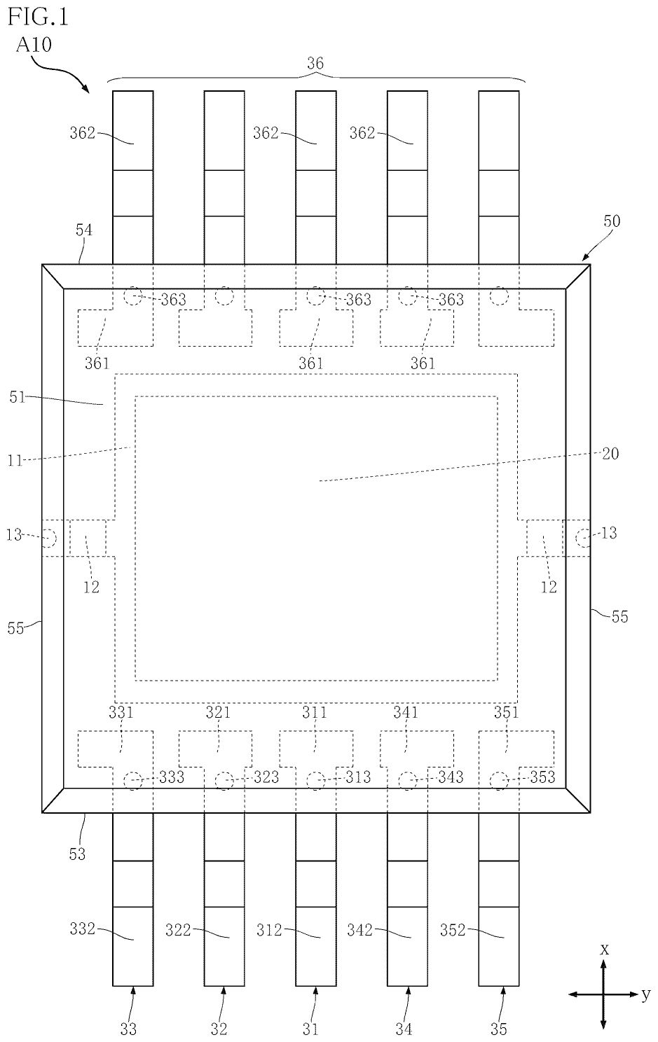

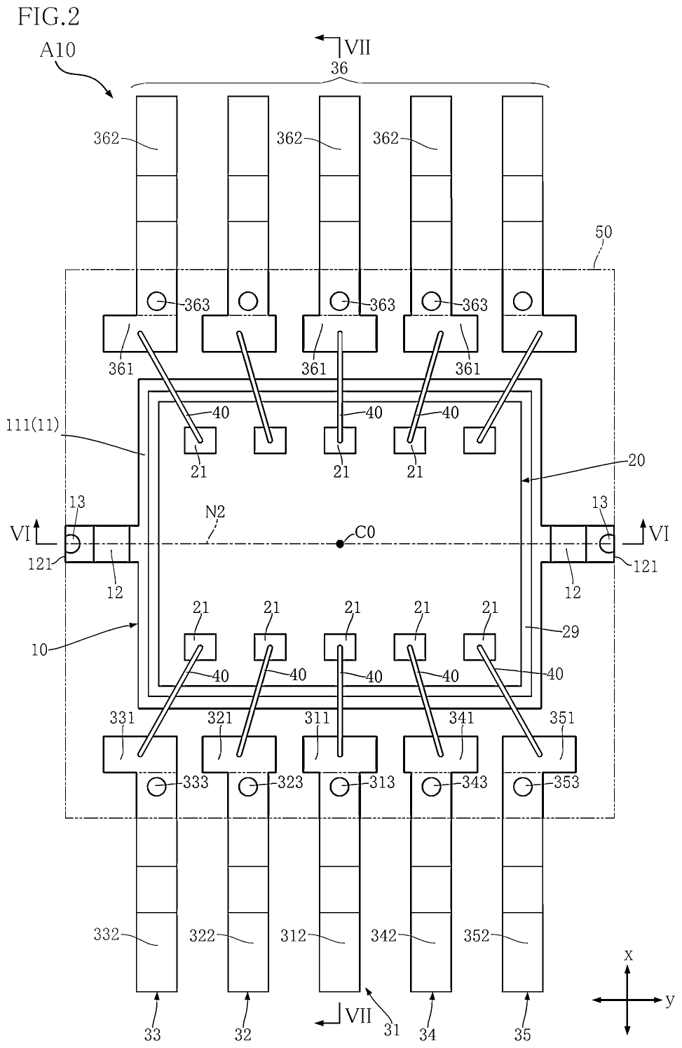

The following describes a semiconductor device A10 according to a first embodiment of the present disclosure, with reference to FIGS. 1 to 9. The semiconductor device A10 is surface-mountable on the wiring boards of various electronic devices. The package format of the semiconductor device A10 is SOP. The semiconductor device A10 includes a die pad 10, a semiconductor element 20, a bonding layer 29, a first lead 31, a second lead 32, a third lead 33, a fourth lead 34, a fifth lead 35, a plurality of sixth leads 36, a plurality of wires 40, and a sealing resin 50. Note that FIGS. 2, 8, and 9 show the sealing resin 50 as transparent for convenience of understanding. In FIGS. 2, 8, and 9, the outer shape of the sealing resin 50 is indicated by an imaginary line (two-dot chain line).

In the description of the semiconductor device A10, the direction in which a first terminal portion 312 (described below) of the first lead 31 is continuous to a first pad portion 311 (described below) of the first lead 31 is referred to as a “first direction x” for convenience. An example of the direction perpendicular to the first direction x is referred to as a “second direction y”. An example of the direction perpendicular to the first direction x and the second direction y is referred to as a “third direction z”. The third direction z is an example of the normal direction of a mounting surface 111 of a pad portion 11 (described below) of the die pad 10.

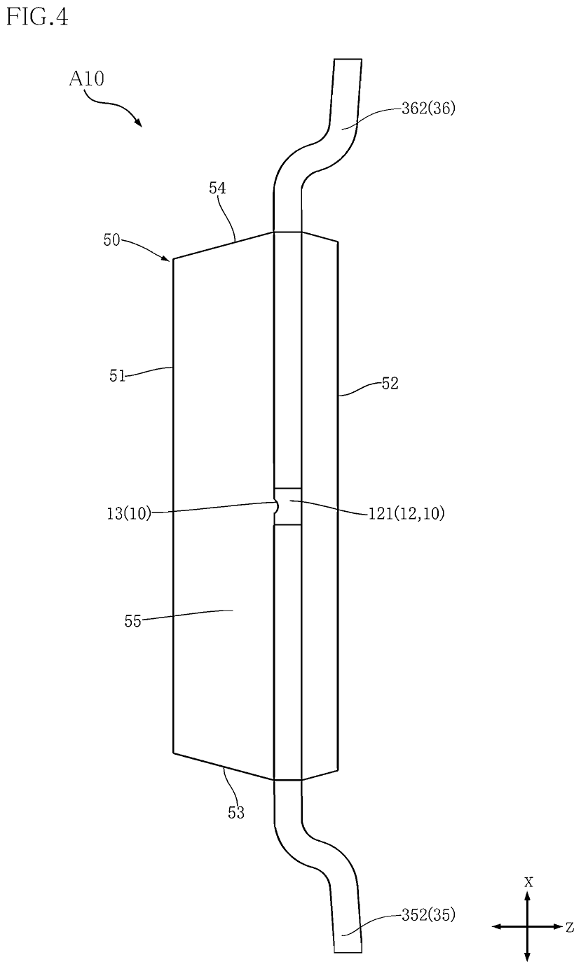

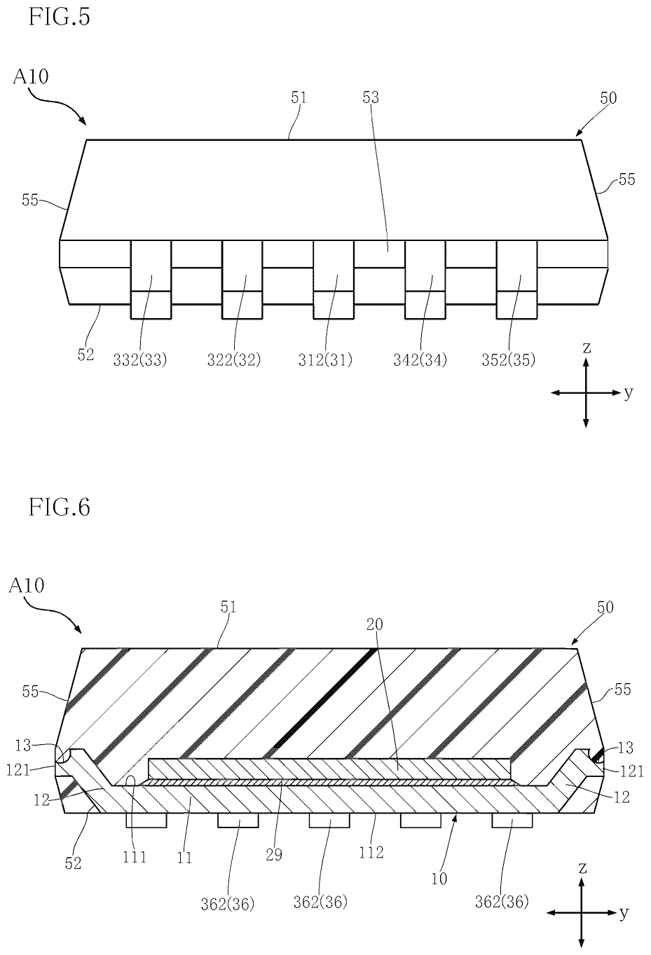

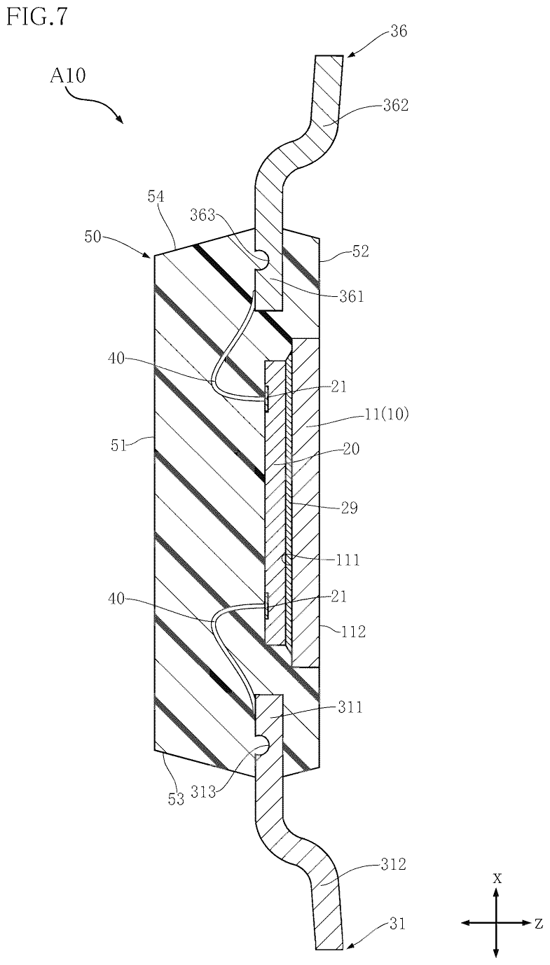

As shown in FIGS. 6 and 7, the sealing resin 50 covers a portion of the die pad 10, the semiconductor element 20, and the wires 40. The sealing resin 50 further covers a portion of each of the first lead 31, the second lead 32, the third lead 33, the fourth lead 34, the fifth lead 35, and the sixth leads 36. The sealing resin 50 is electrically insulative. The sealing resin 50 comprises a black epoxy resin, for example. As shown in FIGS. 4 and 5, the sealing resin 50 has a top surface 51, a bottom surface 52, a first side surface 53, a second side surface 54, and two third side surfaces 55.

As shown in FIGS. 4 to 7, the top surface 51 faces a first side in the third direction z. The top surface 51 faces the same side as a mounting surface 111 of a pad portion 11 (described below) of the die pad 10. The bottom surface 52 faces away from the top surface 51 in the third direction z.

As shown in FIGS. 1, 3, and 4, the first side surface 53 faces a first side in the first direction x. The second side surface 54 faces away from the first side surface 53 in the first direction x. The first side surface 53 and the second side surface 54 are connected to the top surface 51 and the bottom surface 52.

As shown in FIGS. 1, 3, and 5, the two third side surfaces 55 face away from each other in the second direction y. The two third side surfaces 55 are connected to the top surface 51 and the bottom surface 52. The ends of each of the two third side surfaces 55 in the first direction x are connected to the first side surface 53 and the second side surface 54.

As shown in FIGS. 2, 6, and 7, the die pad 10 has the semiconductor element 20 mounted thereon. The die pad 10 is located between the first lead 31 and the sixth leads 36 in the first direction x. Furthermore, the die pad 10 is located opposite from a first terminal portion 312 (described below) of the first lead 31 with respect to a first pad portion 311 (described below) of the first lead 31 in the first direction x. The die pad 10 contains a metal element. The metal element is copper (Cu), for example. The die pad 10, the first lead 31, the second lead 32, the third lead 33, the fourth lead 34, the fifth lead 35, and the sixth leads 36 are formed from the same lead frame. As shown in FIG. 2, the die pad 10 has a pad portion 11 and two suspending portions 12.

As shown in FIGS. 2, 6, and 7, the pad portion 11 has the semiconductor element 20 mounted thereon. The pad portion 11 has a rectangular shape. The pad portion 11 has a mounting surface 111 and a reverse surface 112. The mounting surface 111 and the reverse surface 112 face away from each other in the third direction z. The mounting surface 111 faces the semiconductor element 20. The reverse surface 112 is exposed from the bottom surface 52 of the sealing resin 50. The area of the reverse surface 112 is equal to the area of the mounting surface 111.

As shown in FIGS. 2 and 6, the two suspending portions 12 are located opposite from each other with respect to the pad portion 11 in the second direction y. The two suspending portions 12 are continuous to the pad portion 11. As viewed in the third direction z, the two suspending portions 12 extend in the second direction y. As viewed in the first direction x, the two suspending portions 12 are bent toward the semiconductor element 20 with respect to the pad portion 11 in the third direction z.

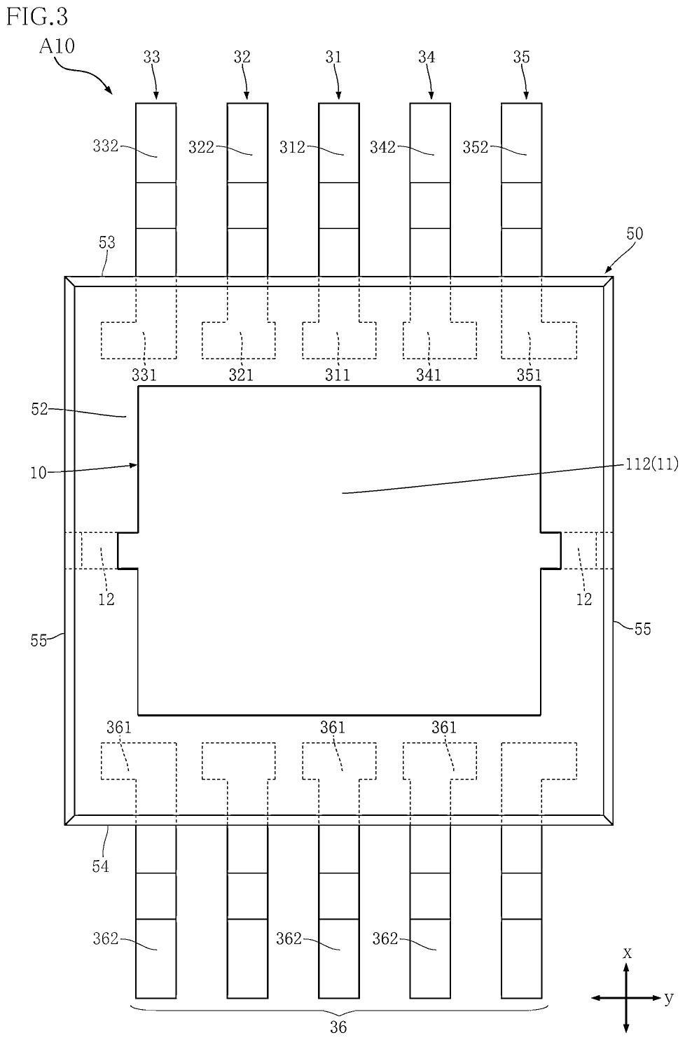

As shown in FIGS. 4 and 6, each of the two suspending portions 12 has an end surface 121. The end surface 121 faces in the second direction y. The end surface 121 of each of the two suspending portions 12 is exposed from a different one of the two third side surfaces 55 of the sealing resin 50. As shown in FIG. 3, each of the two suspending portions 12 includes a portion exposed from the bottom surface 52 of the sealing resin 50. As shown in FIG. 6, the two suspending portions 12 are sandwiched by the sealing resin 50 in the third direction z.

As shown in FIGS. 2, 4, and 6, each of the two suspending portions 12 is provided with a pad recess 13. The pad recess 13 is recessed in the third direction z from the surface of one of the two suspending portions 12 that faces the same side as the mounting surface 111 of the pad portion 11 in the third direction z. The pad recess 13 is connected to the end surface 121 of one of the two suspending portions 12, and is also recessed from the end surface 121. The pad recess 13 accommodates a portion of the sealing resin 50.

As shown in FIGS. 6 and 7, the semiconductor element 20 is mounted on the pad portion 11 of the die pad 10. In the semiconductor device A10, the semiconductor element 20 is an integrated circuit (IC) including a switching element, a capacitive element, and an inductor. The integrated circuit forms a DC-DC converter, for example. The semiconductor element 20 has a plurality of electrodes 21.

As shown in FIGS. 2 and 7, the electrodes 21 are provided on the side opposite from the side that faces the pad portion 11 of the die pad 10 in the third direction z. The electrodes 21 are electrically connected to a circuit configured inside the semiconductor element 20. The composition of the electrodes 21 includes aluminum (Al), for example. Each of the electrodes 21 is electrically connected to one of the first lead 31, the second lead 32, the third lead 33, the fourth lead 34, the fifth lead 35, and the sixth leads 36.

As shown in FIGS. 6 and 7, the bonding layer 29 is located between the mounting surface 111 of the pad portion 11 of the die pad 10 and the semiconductor element 20. The bonding layer 29 is made of a paste (so-called Ag paste) whose main component is an epoxy resin containing silver, for example. The semiconductor element 20 is bonded to the mounting surface 111 via the bonding layer 29.

As shown in FIGS. 1 to 3, the first lead 31 is located opposite from the sixth leads 36 with respect to the die pad 10 in the first direction x. The first lead 31 has a first pad portion 311 and a first terminal portion 312. The first pad portion 311 has a rectangular shape. The first pad portion 311 is covered with the sealing resin 50.

As shown in FIGS. 1 to 3, the first terminal portion 312 is continuous to the first pad portion 311 on the first side in the first direction x. The first terminal portion 312 is located opposite from the die pad 10 with respect to the first pad portion 311 in the first direction x. As viewed in the third direction z, the first terminal portion 312 has a rectangular shape extending in the first direction x. A portion of the first terminal portion 312 is exposed to the outside from the first side surface 53 of the sealing resin 50. As shown in FIG. 7, as viewed in the second direction y, the portion of the first terminal portion 312 exposed to the outside from the sealing resin 50 is bent toward the bottom surface 52 of the sealing resin 50 with respect to the first pad portion 311 in the third direction z. As viewed in the third direction z, the portion of the first terminal portion 312 exposed to the outside from the sealing resin 50 extends in the first direction x.

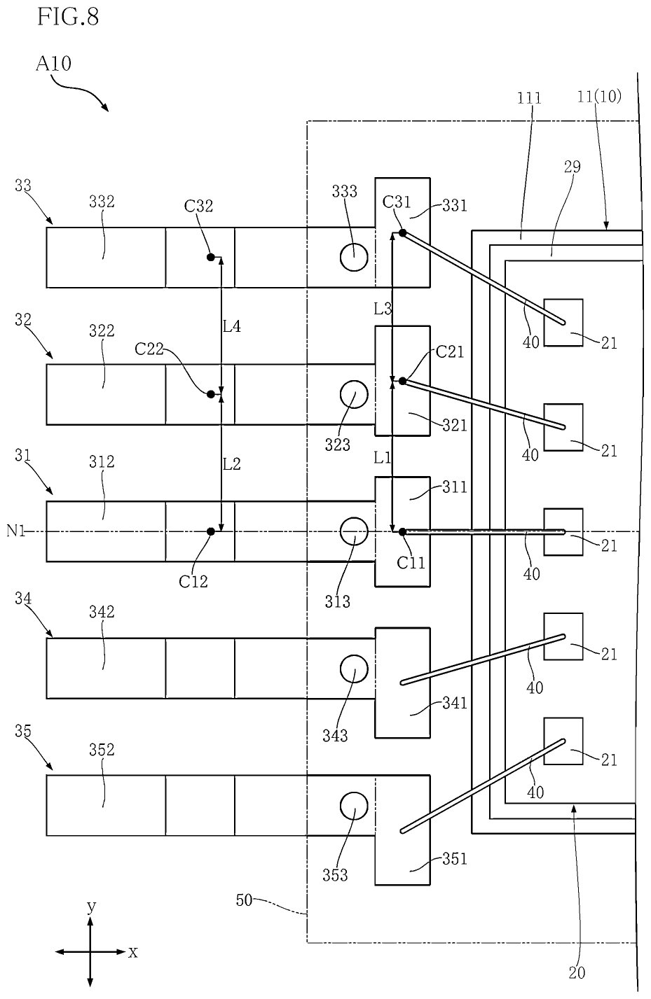

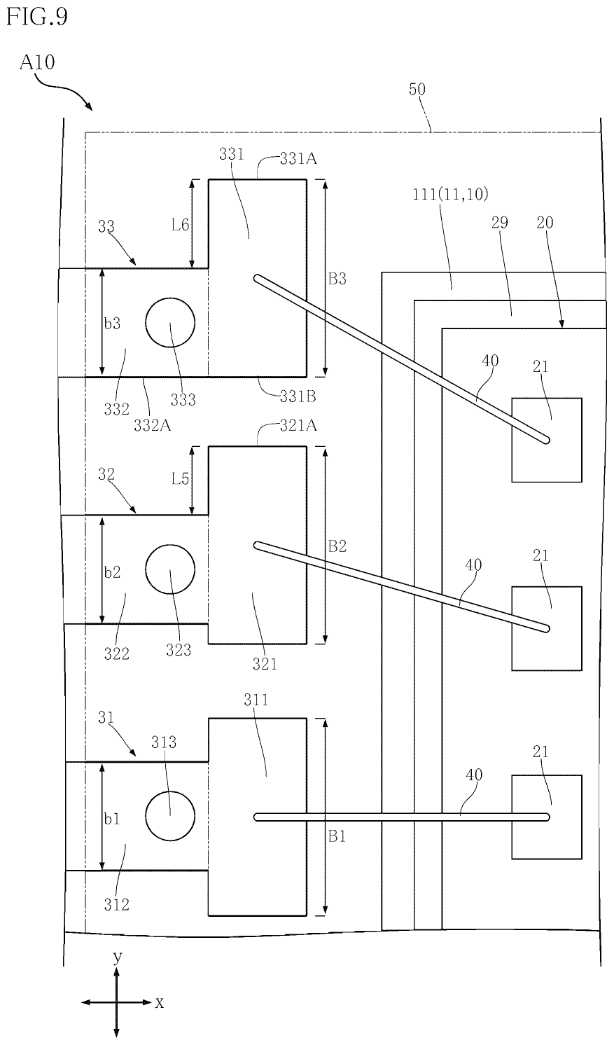

As shown in FIG. 9, a dimension b1 of the first terminal portion 312 in the second direction y is smaller than a dimension B1 of the first pad portion 311 in the second direction y. As shown in FIG. 8, as viewed in the third direction z, the position of a center C12 of the first terminal portion 312 in the second direction y is the same as the position of a center C11 of the first pad portion 311 in the second direction y. Note that the center C11 corresponds to the centroid of the first pad portion 311 as viewed in the third direction z. The center C12 corresponds to the centroid of the first terminal portion 312 as viewed in the third direction z.

As shown in FIGS. 2 and 7, the first terminal portion 312 is formed with a first recess 313. The first recess 313 is recessed in the third direction z from the surface of the first terminal portion 312 facing the same side as the mounting surface 111 of the pad portion 11 of the die pad 10 in the third direction z. The first recess 313 accommodates a portion of the sealing resin 50.

As shown in FIGS. 1 to 3, the second lead 32 is located opposite from the sixth leads 36 with respect to the die pad 10 in the first direction x. The second lead 32 has a second pad portion 321 and a second terminal portion 322. The second pad portion 321 is located adjacent to the first pad portion 311 of the first lead 31 in the second direction y. The second pad portion 321 has a rectangular shape. The second pad portion 321 is covered with the sealing resin 50.

As shown in FIGS. 1 to 3, the second terminal portion 322 is located adjacent to the first terminal portion 312 of the first lead 31 in the second direction y, and is continuous to the second pad portion 321. As viewed in the third direction z, the second terminal portion 322 has a rectangular shape extending in the first direction x. A portion of the second terminal portion 322 is exposed to the outside from the first side surface 53 of the sealing resin 50. As viewed in the second direction y, the portion of the second terminal portion 322 exposed to the outside from the sealing resin 50 is bent toward the bottom surface 52 of the sealing resin 50 with respect to the second pad portion 321 in the third direction z. As viewed in the third direction z, the portion of the second terminal portion 322 exposed to the outside from the sealing resin 50 extends in the first direction x.

As shown in FIG. 9, a dimension b2 of the second terminal portion 322 in the second direction y is smaller than a dimension B2 of the second pad portion 321 in the second direction y. The dimension B2 is equal to the dimension B1 of the first pad portion 311 of the first lead 31 in the second direction y. As shown in FIG. 8, as viewed in the third direction z, the position of a center C22 of the second terminal portion 322 in the second direction y is different from the position of a center C21 of the second pad portion 321 in the second direction y. Note that the center C21 corresponds to the centroid of the second pad portion 321 as viewed in the third direction z. The center C22 corresponds to the centroid of the second terminal portion 322 as viewed in the third direction z.

As shown in FIG. 8, the length of the straight line connecting the center C11 of the first pad portion 311 of the first lead 31 and the center C21 of the second pad portion 321 is defined as a first section length L1. The length of the straight line connecting the center C12 of the first terminal portion 312 of the first lead 31 and the center C22 of the second terminal portion 322 is defined as a second section length L2. In this case, the second section length L2 is different from the first section length L1. In the semiconductor device A10, the second section length L2 is shorter than the first section length L1.

As shown in FIG. 2, the second terminal portion 322 is formed with a second recess 323 recessed in the third direction z. In the third direction z, the second recess 323 is recessed to the same side as the first recess 313 of the first lead 31. The second recess 323 accommodates a portion of the sealing resin 50.

As shown in FIGS. 1 to 3, the third lead 33 is located opposite from the sixth leads 36 with respect to the die pad 10 in the first direction x. The third lead 33 is located opposite from the first lead 31 with respect to the second lead 32 in the second direction y. The third lead 33 has a third pad portion 331 and a third terminal portion 332. The third pad portion 331 is located adjacent to the second pad portion 321 of the second lead 32 in the second direction y. The third pad portion 331 has a rectangular shape. The third pad portion 331 is covered with the sealing resin 50.

As shown in FIGS. 1 to 3, the third terminal portion 332 is located adjacent to the second terminal portion 322 of the second lead 32 in the second direction y, and is continuous to the third pad portion 331. As viewed in the third direction z, the third terminal portion 332 has a rectangular shape extending in the first direction x. A portion of the third terminal portion 332 is exposed to the outside from the first side surface 53 of the sealing resin 50. As viewed in the second direction y, the portion of the third terminal portion 332 exposed to the outside from the sealing resin 50 is bent toward the bottom surface 52 of the sealing resin 50 with respect to the third pad portion 331 in the third direction z. As viewed in the third direction z, the portion of the third terminal portion 332 exposed to the outside from the sealing resin 50 extends in the first direction x.

As shown in FIG. 9, a dimension b3 of the third terminal portion 332 in the second direction y is smaller than a dimension B3 of the third pad portion 331 in the second direction y. The dimension B3 is equal to the dimension B1 of the first pad portion 311 of the first lead 31 in the second direction y. As shown in FIG. 8, as viewed in the third direction z, the position of a center C32 of the third terminal portion 332 in the second direction y is different from the position of a center C31 of the third pad portion 331 in the second direction y. Note that the center C31 corresponds to the centroid of the third pad portion 331 as viewed in the third direction z. The center C32 corresponds to the centroid of the third terminal portion 332 as viewed in the third direction z.

As shown in FIG. 8, the length of the straight line connecting the center C21 of the second pad portion 321 of the second lead 32 and the center C31 of the third pad portion 331 is defined as a third section length L3. The length of the straight line connecting the center C22 of the second terminal portion 322 of the second lead 32 and the center C32 of the third terminal portion 332 is defined as a fourth section length L4. In this case, the fourth section length L4 is shorter than the third section length L3. In the semiconductor device A10, the third section length L3 is equal to the first section length L1 shown in FIG. 8. In addition, the fourth section length L4 is equal to the second section length L2 shown in FIG. 8.

As shown in FIG. 9, the second pad portion 321 of the second lead 32 has a first edge 321A facing the third pad portion 331 as viewed in the third direction z. The first edge 321A extends in the first direction x. As viewed in the third direction z, the third pad portion 331 has a second edge 331A located opposite from the side facing the first edge 321A in the second direction y. The second edge 331A extends in the first direction x. The second edge 331A has the same dimension as the first edge 321A. A distance L5 in the second direction y between the first edge 321A and the second terminal portion 322 of the second lead 32 is shorter than a distance L6 in the second direction y between the second edge 331A and the third terminal portion 332.

As shown in FIG. 9, the third pad portion 331 has a third edge 331B facing the first edge 321A of the second pad portion 321 of the second lead 32. The third edge 331B extends in the first direction x. The third edge 331B has the same dimension as the first edge 321A. As viewed in the third direction z, the third terminal portion 332 has a fourth edge 332A facing the second terminal portion 322 of the second lead 32. The fourth edge 332A extends in the first direction x. In the second direction y, the position of the fourth edge 332A is the same as the position of the third edge 331B.

As shown in FIG. 2, the third terminal portion 332 is formed with a third recess 333 recessed in the third direction z. In the third direction z, the third recess 333 is recessed to the same side as the first recess 313 of the first lead 31. The third recess 333 accommodates a portion of the sealing resin 50.

As shown in FIGS. 1 to 3, the fourth lead 34 is located opposite from the sixth leads 36 with respect to the die pad 10 in the first direction x. The fourth lead 34 is located opposite from the second lead 32 with respect to the first lead 31 in the second direction y. The fourth lead 34 is located adjacent to the first lead 31 in the second direction y. The fourth lead 34 has a fourth pad portion 341 and a fourth terminal portion 342. The fourth pad portion 341 is located adjacent to the first pad portion 311 of the first lead 31 in the second direction y. The fourth pad portion 341 has a rectangular shape. The fourth pad portion 341 is covered with the sealing resin 50.

As shown in FIGS. 1 to 3, the fourth terminal portion 342 is located adjacent to the first terminal portion 312 of the first lead 31 in the second direction y, and is continuous to the fourth pad portion 341. As viewed in the third direction z, the fourth terminal portion 342 has a rectangular shape extending in the first direction x. A portion of the fourth terminal portion 342 is exposed to the outside from the first side surface 53 of the sealing resin 50. As viewed in the second direction y, the portion of the fourth terminal portion 342 exposed to the outside from the sealing resin 50 is bent toward the bottom surface 52 of the sealing resin 50 with respect to the fourth pad portion 341 in the third direction z. As viewed in the third direction z, the portion of the fourth terminal portion 342 exposed to the outside from the sealing resin 50 extends in the first direction x.

As shown in FIG. 8, the second lead 32 and the fourth lead 34 are axisymmetric with respect to an axis N1. The axis N1 extends in the first direction x. The axis N1 passes through the center C11 of the first pad portion 311 of the first lead 31.

As shown in FIG. 2, the fourth terminal portion 342 is formed with a fourth recess 343 recessed in the third direction z. In the third direction z, the fourth recess 343 is recessed to the same side as the first recess 313 of the first lead 31. The fourth recess 343 accommodates a portion of the sealing resin 50.

As shown in FIGS. 1 to 3, the fifth lead 35 is located opposite from the sixth leads 36 with respect to the die pad 10 in the first direction x. The fifth lead 35 is located opposite from the first lead 31 with respect to the fourth lead 34 in the second direction y. The fifth lead 35 is located adjacent to the fourth lead 34 in the second direction y. The fifth lead 35 has a fifth pad portion 351 and a fifth terminal portion 352. The fifth pad portion 351 is located adjacent to the fourth pad portion 341 of the fourth lead 34 in the second direction y. The fifth pad portion 351 has a rectangular shape. The fifth pad portion 351 is covered with the sealing resin 50.

As shown in FIGS. 1 to 3, the fifth terminal portion 352 is located adjacent to the fourth terminal portion 342 of the fourth lead 34 in the second direction y, and is continuous to the fifth pad portion 351. As viewed in the third direction z, the fifth terminal portion 352 has a rectangular shape extending in the first direction x. A portion of the fifth terminal portion 352 is exposed to the outside from the first side surface 53 of the sealing resin 50. As viewed in the second direction y, the portion of the fifth terminal portion 352 exposed to the outside from the sealing resin 50 is bent toward the bottom surface 52 of the sealing resin 50 with respect to the fifth pad portion 351 in the third direction z. As viewed in the third direction z, the portion of the fifth terminal portion 352 exposed to the outside from the sealing resin 50 extends in the first direction x.

As shown in FIG. 8, the third lead 33 and the fifth lead 35 are axisymmetric with respect to the axis N1.

As shown in FIG. 2, the fifth terminal portion 352 is formed with a fifth recess 353 recessed in the third direction z. In the third direction z, the fifth recess 353 is recessed to the same side as the first recess 313 of the first lead 31. The fifth recess 353 accommodates a portion of the sealing resin 50.

As shown in FIGS. 1 to 3, the sixth leads 36 are located opposite from the first lead 31 with respect to the die pad 10 in the first direction x. The sixth leads 36 are aligned along the second direction y. Each of the sixth leads 36 has a sixth pad portion 361 and a sixth terminal portion 362. In each of the sixth leads 36, the sixth pad portion 361 is located between the die pad 10 and the sixth terminal portion 362 in the first direction x. The sixth pad portion 361 has a rectangular shape. The sixth pad portion 361 is covered with the sealing resin 50.

As shown in FIGS. 1 to 3, the sixth terminal portion 362 is continuous to the sixth pad portion 361. As viewed in the third direction z, the sixth terminal portion 362 has a rectangular shape extending in the first direction x. A portion of the sixth terminal portion 362 is exposed to the outside from the second side surface 54 of the sealing resin 50. As shown in FIG. 7, as viewed in the second direction y, the portion of the sixth terminal portion 362 exposed to the outside from the sealing resin 50 is bent toward the bottom surface 52 of the sealing resin 50 with respect to the sixth pad portion 361 in the third direction z. As viewed in the third direction z, the portion of the sixth terminal portion 362 exposed to the outside from the sealing resin 60 extends in the first direction x.

As shown in FIG. 2, the sixth leads 36 and the first lead 31, the second lead 32, the third lead 33, the fourth lead 34, and the fifth lead 35 are axisymmetric with respect to an axis N2. The axis N2 extends in the second direction y. The axis N2 passes through a center CO of the pad portion 11 of the die pad 10. Note that the center CO corresponds to the centroid of the pad portion 11 as viewed in the third direction z.

As viewed in FIGS. 2 and 7, the sixth terminal portion 362 of each sixth lead 36 is formed with a sixth recess 363 recessed in the third direction z. In the third direction z, the sixth recess 363 is recessed to the same side as the first recess 313 of the first lead 31. The sixth recess 363 accommodates a portion of the sealing resin 50.

As shown in FIG. 2, each of the wires 40 is electrically bonded to one of the electrodes 21 of the semiconductor element 20, and to one of the first pad portion 311 of the first lead 31, the second pad portion 321 of the second lead 32, the third pad portion 331 of the third lead 33, the fourth pad portion 341 of the fourth lead 34, the fifth pad portion 351 of the fifth lead 35, and the sixth pad portions 361 of the sixth leads 36. As a result, the semiconductor element 20 is electrically connected to the first lead 31, the second lead 32, the third lead 33, the fourth lead 34, the fifth lead 35, and the sixth leads 36. The composition of the wires 40 includes gold (Au), for example. Alternatively, each of the wires 40 may include a core material containing copper, and a covering material containing palladium (Pd) and covering the core material.

The following describes advantages of the semiconductor device A10.

The semiconductor device A10 includes the first lead 31 having the first pad portion 311 and the first terminal portion 312, and the second lead 32 having the second pad portion 321 and the second terminal portion 322 and located adjacent to the first lead 31 in the second direction y. A portion of each of the first terminal portion 312 and the second terminal portion 322 is exposed to the outside from the sealing resin 50. As viewed in the third direction z, the length of the straight line connecting the center C11 of the first pad portion 311 and the center C21 of the second pad portion 321 is defined as the first section length L1. As viewed in the third direction z, the length of the straight line connecting the center C12 of the first terminal portion 312 and the center C22 of the second terminal portion 322 is defined as the second section length L2. In this case, the second section length L2 is different from the first section length L1 (see FIG. 8). In the semiconductor device A10 having this configuration, the distance between the first terminal portion 312 and the second terminal portion 322 can be freely changed without changing the size of each of the first pad portion 311 and the first terminal portion 312. Thus, according to this configuration, it is possible in the semiconductor device A10 to freely set the distance between the first terminal portion 312 and the second terminal portion 322 exposed from the sealing resin 50 while securing the bonding area of each of the first pad portion 311 and the second pad portion 321 for the wires 40.

In the semiconductor device A10, the second section length L2 is shorter than the first section length L1. This configuration allows the distance between the first terminal portion 312 and the second terminal portion 322 exposed from the sealing resin 50 to be further shortened. This makes it possible to mount the semiconductor device A10 onto a wiring board having a denser wiring pattern.

The semiconductor device A10 further includes the third lead 33 having the third pad portion 331 and the third terminal portion 332 and located adjacent to the second lead 32 in the second direction y. A portion of the third terminal portion 332 is exposed to the outside from the sealing resin 50. As viewed in the third direction z, the second pad portion 321 has the first edge 321A. As viewed in the third direction z, the third pad portion 331 has the second edge 331A. The distance L5 in the second direction y between the first edge 321A and the second terminal portion 322 is shorter than the distance L6 in the second direction y between the second edge 331A and the third terminal portion 332 (see FIG. 9). With this configuration, even when the position of the center C12 in the second direction y is the same as the position of the center C11 in the second direction y, the distance between the second pad portion 321 and the third pad portion 331 can be equal to the distance between the first pad portion 311 and the second pad portion 321. This makes it possible to suppress a decrease in the dielectric strength of the semiconductor device A10 caused by the distances between the first pad portion 311, the second pad portion 321, and the third pad portion 331.

As viewed in the third direction z, the third pad portion 331 has the third edge 331B. As viewed in the third direction z, the third terminal portion 332 has the fourth edge 332A. In the second direction y, the position of the fourth edge 332A is the same as the position of the third edge 331B. With this configuration, when the sealing resin 50 is formed in the manufacturing of the semiconductor device A10, the molten resin in contact with the third edge 331B and the fourth edge 332A can flow more smoothly. This makes it possible to suppress voids introduced into the sealing resin 50.

The first terminal portion 312 is formed with the first recess 313 recessed in the third direction z. A portion of the sealing resin 50 is accommodated in the first recess 313. With this configuration, the sealing resin 50 exerts an anchoring effect on the first lead 31. This makes it possible to attach the sealing resin 50 to the first lead 31 more firmly.

The semiconductor device A10 further includes the die pad 10 on which the semiconductor element 20 is mounted. The die pad 10 has the reverse surface 112 facing away from the side that faces the semiconductor element 20 in the third direction z. The reverse surface 112 is exposed from the sealing resin 50. This configuration can improve the heat dissipation of the semiconductor device A10.

The die pad 10 has the pad portion 11 on which the semiconductor element 20 is mounted, and the two suspending portions 12 located opposite from each other with respect to the pad portion 11 in the second direction y and continuous to the pad portion 11. As viewed in the first direction x, the two suspending portions 12 are bent toward the semiconductor element 20 with respect to the pad portion 11 in the third direction z. As a result, the two suspending portions 12 are sandwiched by the sealing resin 50 in the third direction z. Thus, even when the reverse surface 112 of the die pad 10 is exposed from the sealing resin 50, the die pad 10 is prevented from falling off from the sealing resin 50.

### Second Embodiment

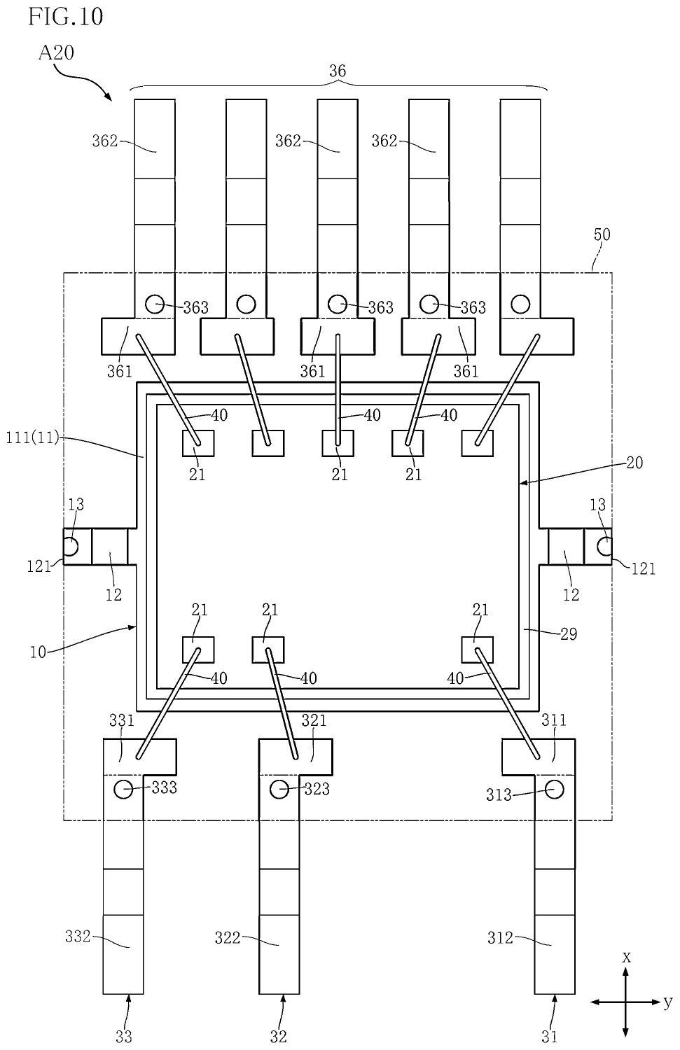

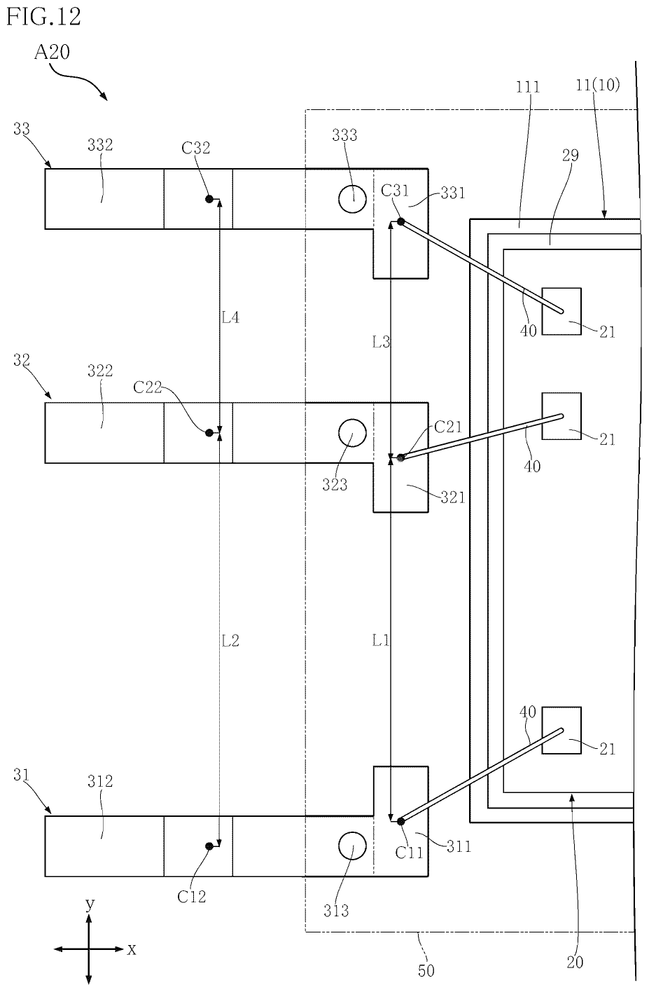

The following describes a semiconductor device A20 according to a second embodiment of the present disclosure, with reference to FIGS. 10 to 12. In these figures, elements that are the same as or similar to the elements of the semiconductor device A10 are provided with the same reference numerals, and descriptions thereof are omitted. Note that FIGS. 10 and 12 show the sealing resin 50 as transparent for convenience of understanding. In FIGS. 10 and 12, the outer shape of the sealing resin 50 is indicated by an imaginary line.

The semiconductor device A20 is different from the semiconductor device A10 in the configurations of the first lead 31, the second lead 32, and the third lead 33, and in not including the fourth lead 34 or the fifth lead 35.

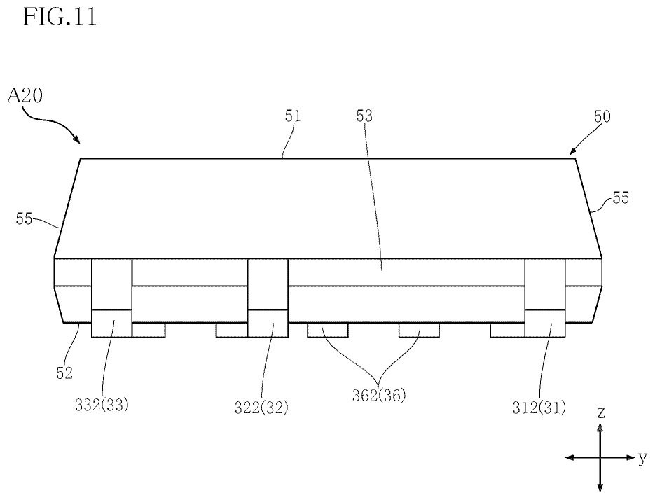

As shown in FIGS. 10 and 11, the semiconductor device A20 does not include the fourth lead 34 or the fifth lead 35. Accordingly, the number of electrodes 21 of the semiconductor element 20 and the number of wires 40 are smaller than those in the semiconductor device A10.

As shown in FIG. 12, the second section length L2 in the semiconductor device A20 is longer than the first section length L1. The third section length L3 is shorter than the first section length L1. The fourth section length L4 is shorter than the second section length L2. The fourth section length L4 is equal to the third section length L3.

The following describes advantages of the semiconductor device A20.

The semiconductor device A20 includes the first lead 31 having the first pad portion 311 and the first terminal portion 312, and the second lead 32 having the second pad portion 321 and the second terminal portion 322 and located adjacent to the first lead 31 in the second direction y. A portion of each of the first terminal portion 312 and the second terminal portion 322 is exposed to the outside from the sealing resin 50. As viewed in the third direction z, the length of the straight line connecting the center C11 of the first pad portion 311 and the center C21 of the second pad portion 321 is defined as the first section length L1. As viewed in the third direction z, the length of the straight line connecting the center C12 of the first terminal portion 312 and the center C22 of the second terminal portion 322 is defined as the second section length L2. In this case, the second section length L2 is different from the first section length L1 (see FIG. 12). Thus, according to this configuration, it is possible even in the semiconductor device A20 to freely set the distance between the first terminal portion 312 and the second terminal portion 322 exposed from the sealing resin 50 while securing the bonding area of each of the first pad portion 311 and the second pad portion 321 for the wires 40.

In the semiconductor device A20, the second section length L2 is longer than the first section length L1. This configuration allows the distance between the first terminal portion 312 and the second terminal portion 322 exposed from the sealing resin 50 to be further increased. As a result, the creepage distance of the sealing resin 50 (the distance along the surface of the sealing resin 50) from the first terminal portion 312 to the second terminal portion 322 is further increased. Thus, even when the potential difference between the voltage applied to the first lead 31 and the voltage applied to the second lead 32 is large, a decrease in the dielectric strength of the semiconductor device A20 can be suppressed.

Furthermore, the semiconductor device A20 has configurations similar to the semiconductor device A10, whereby the semiconductor device A20 also has advantages owing to the configurations.

The present disclosure is not limited to the above embodiments. Various design changes can be made to the specific configurations of the elements in the present disclosure.

The present disclosure includes the embodiments described in the following clauses.

### Clause 1.

A semiconductor device comprising:
a semiconductor element including a plurality of electrodes;
a first lead including a first pad portion, and a first terminal portion continuous to the first pad portion on a first side in a first direction;
a second lead including a second pad portion located adjacent to the first pad portion in a second direction perpendicular to the first direction, and a second terminal portion located adjacent to the first terminal portion in the second direction and continuous to the second pad portion;
a plurality of wires each electrically bonded to one of the plurality of electrodes and to one of the first pad portion and the second pad portion; and
a sealing resin covering a portion of each of the first lead and the second lead and the semiconductor element,
wherein a portion of each of the first terminal portion and the second terminal portion is exposed to an outside from the sealing resin,
as viewed in a third direction perpendicular to the first direction and the second direction, a length of a straight line connecting a center of the first pad portion and a center of the second pad portion is defined as a first section length,
as viewed in the third direction, a length of a straight line connecting a center of the first terminal portion and a center of the second terminal portion is defined as a second section length, and
the second section length is different from the first section length.

### Clause 2.

The semiconductor device according to clause 1, wherein a dimension of the first terminal portion in the second direction is smaller than a dimension of the first pad portion in the second direction, and
a dimension of the second terminal portion in the second direction is smaller than a dimension of the second pad portion in the second direction.

### Clause 3.

The semiconductor device according to clause 2, wherein the dimension of the second pad portion in the second direction is a same as the dimension of the first pad portion in the second direction.

### Clause 4.

The semiconductor device according to clause 2 or 3, wherein the second section length is shorter than the first section length.

### Clause 5.

The semiconductor device according to clause 4, further comprising a third lead located opposite from the first lead with respect to the second lead in the second direction and partially covered with the sealing resin,
wherein the third lead includes a third pad portion located adjacent to the second pad portion in the second direction, and a third terminal portion located adjacent to the second terminal portion in the second direction and continuous to the third pad portion,
a portion of the third terminal portion is exposed to the outside from the sealing resin,
as viewed in the third direction, a length of a straight line connecting the center of the second pad portion and a center of the third pad portion is defined as a third section length,
as viewed in the third direction, a length of a straight line connecting the center of the second terminal portion and a center of the third terminal portion is defined as a fourth section length, and the fourth section length is shorter than the third section length.

### Clause 6.

The semiconductor device according to clause 5, wherein a dimension of the third terminal portion in the second direction is smaller than a dimension of the third pad portion in the second direction.

### Clause 7.

The semiconductor device according to clause 6, wherein the third section length is equal to the first section length, and the fourth section length is equal to the second section length.

### Clause 8.

The semiconductor device according to clause 6 or 7, wherein as viewed in the third direction, the second pad portion includes a first edge facing the third pad portion,
as viewed in the third direction, the third pad portion includes a second edge located opposite from a side facing the first edge in the second direction, and
a distance in the second direction between the first edge and the second terminal portion is shorter than a distance in the second direction between the second edge and the third terminal portion.

### Clause 9.

The semiconductor device according to clause 8, wherein as viewed in the third direction, the third pad portion includes a third edge facing the first edge,
as viewed in the third direction, the third terminal portion includes a fourth edge facing the second terminal portion, and
as viewed in the second direction, a position of the fourth edge is a same as a position of the third edge.

### Clause 10.

The semiconductor device according to clause 8 or 9, further comprising a fourth lead located opposite from the second lead with respect to the first lead in the second direction and partially covered with the sealing resin,
the fourth lead is located adjacent to the first lead in the second direction, and
as viewed in the third direction, the second lead and the fourth lead extend in the first direction, and are axisymmetric with respect to an axis passing through the center of the first pad portion.

### Clause 11.

The semiconductor device according to clause 10, further comprising a fifth lead located opposite from the first lead with respect to the fourth lead in the second direction and partially covered with the sealing resin,
the fifth lead is located adjacent to the fourth lead in the second direction, and
as viewed in the third direction, the third lead and the fifth lead are axisymmetric with respect to the axis.

### Clause 12.

The semiconductor device according to clause 2 or 3, wherein the second section length is longer than the first section length.

### Clause 13.

The semiconductor device according to any of clauses 1 to 12, further comprising a die pad on which the semiconductor element is mounted,
wherein the die pad is located opposite from the first terminal portion with respect to the first pad portion in the first direction.

### Clause 14.

The semiconductor device according to clause 13, wherein the die pad includes a reverse surface facing away from a side facing the semiconductor element in the third direction, and the reverse surface is exposed from the sealing resin.

### Clause 15.

The semiconductor device according to clause 14, wherein the die pad includes a pad portion on which the semiconductor element is mounted, and two suspending portions located opposite from each other with respect to the pad portion in the second direction and continuous to the pad portion, and
as viewed in the first direction, the two suspending portions are bent toward the semiconductor element with respect to the pad portion in the third direction.

### Clause 16.

The semiconductor device according to any of clauses 1 to 15, wherein the first terminal portion is formed with a recess recessed in the third direction, and
a portion of the sealing resin is accommodated in the recess.

### Clause 17.

The semiconductor device according to any of clauses 1 to 16, wherein as viewed in the third direction, the portion of each of the first terminal portion and the second terminal portion that is exposed to the outside from the sealing resin extends in the first direction.

### REFERENCE NUMERALS

A10, A20: Semiconductor device 10: Die pad
11: Pad portion 111: Mounting surface
112: Reverse surface 12: Suspending portion
12: End surface 13: Pad recess
20: Semiconductor element 21: Electrode
29: Bonding layer 31: First lead
311: First pad portion 312: First terminal portion
313: First recess 32: Second lead
321: Second pad portion 321A: First edge
322: Second terminal portion 323: Second recess
33: Third lead 331: Third pad portion
331A: Second edge 331B: Third edge
332: Third terminal portion 332A: Fourth edge
333: Third recess 34: Fourth lead
341: Fourth pad portion 342: Fourth terminal portion
343: Fourth recess 35: Fifth lead
351: Fifth pad portion 352: Fifth terminal portion
353: Fifth recess 36: Sixth lead
361: Sixth pad portion 362: Sixth terminal portion
363: Sixth recess 40: Wire
50: Sealing resin 51: Top surface
52: Bottom surface 53: First side surface
54: Second side surface 55: Third side surface
L1: First section length L2: Second section length
L3: Third section length L4: Fourth section length
x: First direction y: Second direction
z: Third direction

1. A semiconductor device comprising:
a semiconductor element including a plurality of electrodes;
a first lead including a first pad portion, and a first terminal portion continuous to the first pad portion on a first side in a first direction;
a second lead including a second pad portion located adjacent to the first pad portion in a second direction perpendicular to the first direction, and a second terminal portion located adjacent to the first terminal portion in the second direction and continuous to the second pad portion;
a plurality of wires each electrically bonded to one of the plurality of electrodes and to one of the first pad portion and the second pad portion; and
a sealing resin covering a portion of each of the first lead and the second lead and the semiconductor element,
wherein a portion of each of the first terminal portion and the second terminal portion is exposed to an outside from the sealing resin,
as viewed in a third direction perpendicular to the first direction and the second direction, a length of a straight line connecting a center of the first pad portion and a center of the second pad portion is defined as a first section length,
as viewed in the third direction, a length of a straight line connecting a center of the first terminal portion and a center of the second terminal portion is defined as a second section length, and
the second section length is different from the first section length.

2. The semiconductor device according to claim 1, wherein a dimension of the first terminal portion in the second direction is smaller than a dimension of the first pad portion in the second direction, and
a dimension of the second terminal portion in the second direction is smaller than a dimension of the second pad portion in the second direction.

3. The semiconductor device according to claim 2, wherein the dimension of the second pad portion in the second direction is a same as the dimension of the first pad portion in the second direction.

4. The semiconductor device according to claim 2, wherein the second section length is shorter than the first section length.

5. The semiconductor device according to claim 4, further comprising a third lead located opposite from the first lead with respect to the second lead in the second direction and partially covered with the sealing resin,
wherein the third lead includes a third pad portion located adjacent to the second pad portion in the second direction, and a third terminal portion located adjacent to the second terminal portion in the second direction and continuous to the third pad portion,
a portion of the third terminal portion is exposed to the outside from the sealing resin,
as viewed in the third direction, a length of a straight line connecting the center of the second pad portion and a center of the third pad portion is defined as a third section length,
as viewed in the third direction, a length of a straight line connecting the center of the second terminal portion and a center of the third terminal portion is defined as a fourth section length, and
the fourth section length is shorter than the third section length.

6. The semiconductor device according to claim 5, wherein a dimension of the third terminal portion in the second direction is smaller than a dimension of the third pad portion in the second direction.

7. The semiconductor device according to claim 6, wherein the third section length is equal to the first section length, and
the fourth section length is equal to the second section length.

8. The semiconductor device according to claim 6, wherein as viewed in the third direction, the second pad portion includes a first edge facing the third pad portion,
as viewed in the third direction, the third pad portion includes a second edge located opposite from a side facing the first edge in the second direction, and
a distance in the second direction between the first edge and the second terminal portion is shorter than a distance in the second direction between the second edge and the third terminal portion.

9. The semiconductor device according to claim 8, wherein as viewed in the third direction, the third pad portion includes a third edge facing the first edge,
as viewed in the third direction, the third terminal portion includes a fourth edge facing the second terminal portion, and
as viewed in the second direction, a position of the fourth edge is a same as a position of the third edge.

10. The semiconductor device according to claim 8, further comprising a fourth lead located opposite from the second lead with respect to the first lead in the second direction and partially covered with the sealing resin,
the fourth lead is located adjacent to the first lead in the second direction, and
as viewed in the third direction, the second lead and the fourth lead extend in the first direction, and are axisymmetric with respect to an axis passing through the center of the first pad portion.

11. The semiconductor device according to claim 10, further comprising a fifth lead located opposite from the first lead with respect to the fourth lead in the second direction and partially covered with the sealing resin,
the fifth lead is located adjacent to the fourth lead in the second direction, and
as viewed in the third direction, the third lead and the fifth lead are axisymmetric with respect to the axis.

12. The semiconductor device according to claim 2, wherein the second section length is longer than the first section length.

13. The semiconductor device according to claim 1, further comprising a die pad on which the semiconductor element is mounted,
wherein the die pad is located opposite from the first terminal portion with respect to the first pad portion in the first direction.

14. The semiconductor device according to claim 13, wherein the die pad includes a reverse surface facing away from a side facing the semiconductor element in the third direction, and
the reverse surface is exposed from the sealing resin.

15. The semiconductor device according to claim 14, wherein the die pad includes a pad portion on which the semiconductor element is mounted, and two suspending portions located opposite from each other with respect to the pad portion in the second direction and continuous to the pad portion, and
as viewed in the first direction, the two suspending portions are bent toward the semiconductor element with respect to the pad portion in the third direction.

16. The semiconductor device according to claim 1, wherein the first terminal portion is formed with a recess recessed in the third direction, and
a portion of the sealing resin is accommodated in the recess.

17. The semiconductor device according to claim 1, wherein as viewed in the third direction, the portion of each of the first terminal portion and the second terminal portion that is exposed to the outside from the sealing resin extends in the first direction.
